(19) United States
(12) Patent Application Publication
(10) Pub. No.: US 2014/0167097 A1
(43) Pub. Date: Jun. 19, 2014

(54) OPTOELECTRONIC DEVICE AND METHOD FOR MANUFACTURING THE SAME

(71) Applicant: EPISTAR CORPORATION, Hsinchu (TW)

(72) Inventors: HSIN-HSIEN WU, Hsinchu (TW); YU-YAO LIN, Hsinchu (TW); YEN-CHIH CHEN, Hsinchu (TW); CHIEN-YUAN TSENG, Hsinchu (TW); CHUN-TA YU, Hsinchu (TW); CHENG-HSIUNG YEN, Hsinchu (TW); SHIH-CHUN LING, Hsinchu (TW); TSUN-KAI KO, Hsinchu (TW); DE-SHAN KUO, Hsinchu (TW)

(73) Assignee: EPISTAR CORPORATION, Hsinchu (TW)

(21) Appl. No.: 14/104,017

(22) Filed: Dec. 12, 2013

(30) Foreign Application Priority Data
Dec. 14, 2012 (TW) 101147715

(51) Int. Cl. H01L 33/24

(52) U.S. Cl. CPC H01L 33/24
USPC 257/101; 438/37

(57) ABSTRACT

A method of fabricating an optoelectronic device comprising, providing a substrate, wherein the substrate comprises a first major surface and a second major surface opposite to the first major surface; forming a semiconductor epitaxial stack on the first major surface including a first conductive-type semiconductor layer having a first doping concentration, an active layer, and a second conductive-type semiconductor layer wherein the semiconductor epitaxial stack having four boundaries and a geometric center; and forming a plurality of the hollow components in the first conductive-type semiconductor layer wherein the plurality of the hollow components is formed from the boundary of the semiconductor epitaxial stack to the geometric center of the semiconductor epitaxial stack.

### RELATED APPLICATION

This application claims the priority to and the benefit of TW application Ser. No. 101147715 filed on Dec. 14, 2012; the contents of which is incorporated herein by reference in its entirety.

### BACKGROUND

1. Technical Field

The present disclosure relates to an optoelectronic device having a plurality of the hollow components formed inside the semiconductor layer.

2. Description of the Related Art

The light radiation theory of light emitting diode (LED) is to generate light from the energy released by the electron moving between an n-type semiconductor and a p-type semiconductor. Because the light radiation theory of LED is different from the incandescent light which heats the filament, the LED is called a “cold” light source. Moreover, the LED is more sustainable, longevous, light and handy, and less power-consumption, therefore it is considered as an alternative light source for the illumination markets. The LED applies to various applications like the traffic signal, backlight module, street light, and medical instruments, and is gradually replacing the traditional lighting sources.

FIG. 1 illustrates the structure of a conventional light emitting device 100 which includes a transparent substrate 10, a semiconductor stack 12 formed above the transparent substrate 10, and an electrode 14 formed above the semiconductor stack 12, wherein the semiconductor stack 12 includes, from the top, a first conductive-type semiconductor layer 120, an active layer 122, and a second conductive-type semiconductor layer 124.

In addition, the light emitting device 100 can be further connected to other components in order to form a light emitting apparatus. FIG. 2 illustrates a conventional light emitting apparatus including a sub-mount 20 carrying an electrical circuit 202, a solder 22 formed above the sub-mount 20 wherein the light emitting device 100 is bonded to the sub-mount 20 and is electrically connected with the electric circuit 202 on the sub-mount 20 by the solder 22, and an electrical connection structure 24 that electrically connects the electrode 14 of the light emitting device 100 to the electric circuit 202 on the sub-mount 20. The sub-mount 20 may be a lead frame or a large size mounting substrate in order to facilitate circuit design and enhance heat dissipation.

Nevertheless, because the surface of the transparent substrate 10 of the conventional light emitting device 100 as illustrated in FIG. 1 is substantially flat and the refractive index of the transparent substrate 10 is different from the refractive index of the external environment, the total internal reflection (TIR) occurs when a light A emitted from the active layer 122. Therefore the light extraction efficiency of the light emitting device 100 is reduced drastically.

### SUMMARY OF THE DISCLOSURE

A method of fabricating an optoelectronic device comprising, providing a substrate, wherein the substrate comprises a first major surface and a second major surface opposite to the first major surface; forming a semiconductor epitaxial stack on the first major surface including a first conductive-type semiconductor layer having a first doping concentration, an active layer, and a second conductive-type semiconductor layer wherein the semiconductor epitaxial stack having four boundaries and a geometric center; and forming a plurality of the hollow components in the first conductive-type semiconductor layer wherein the plurality of the hollow components is formed from the boundary of the semiconductor epitaxial stack to the geometric center of the semiconductor epitaxial stack.

### BRIEF DESCRIPTION OF DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1 illustrates the structure of a conventional light emitting device.

FIG. 2 illustrates the structure of a conventional light emitting apparatus.

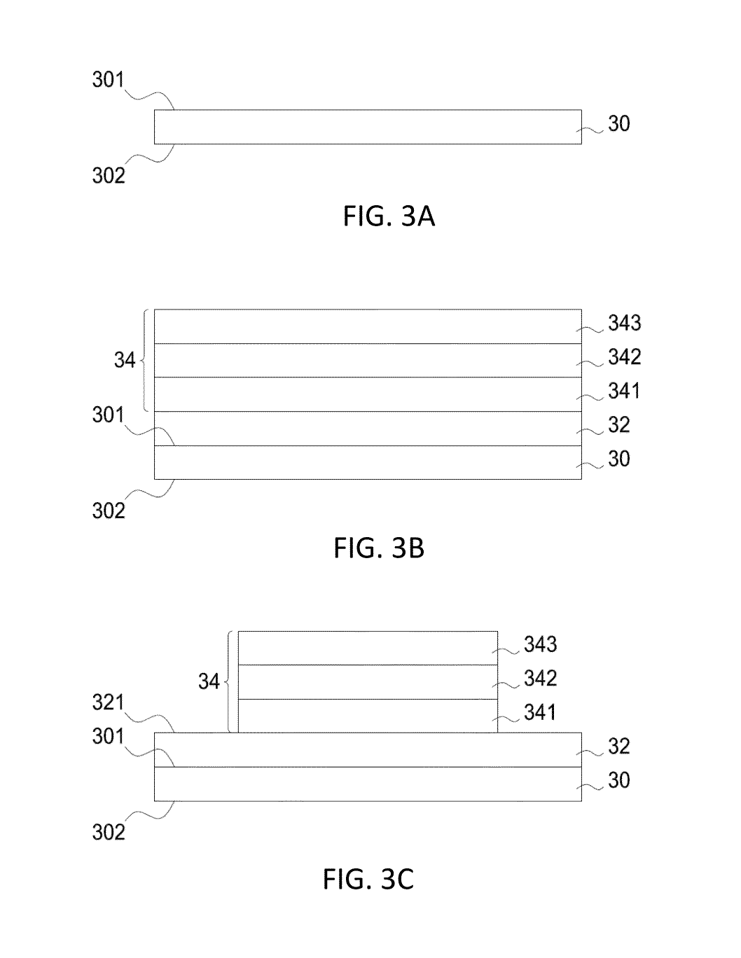

FIGS. 3A˜3E illustrate a process flow of a method of fabricating an optoelectronic device of the first embodiment in the present disclosure.

FIGS. 3F-1˜3F-4 illustrate the optical microscope images of the first conductive-type semiconductor layer in the present disclosure.

FIG. 3F-5 illustrates the schematic diagram of the upper surface of the first conductive-type semiconductor layer in the present disclosure.

FIG. 3F-6 illustrates the three-dimensional schematic view of the first conductive-type semiconductor layer in the present disclosure.

FIGS. 3F-7˜3F-8 illustrate scanning electron microscopy (SEM) pictures of the first conductive-type semiconductor layer in the present disclosure.

FIGS. 4A˜4B illustrate a process flow of a method of fabricating an optoelectronic device of the second embodiment in the present disclosure.

FIGS. 5A˜5B illustrate a process flow of a method of fabricating an optoelectronic device of the third embodiment in the present disclosure.

FIGS. 6A˜6C illustrate an LED module of an embodiment in the present disclosure.

FIGS. 7A˜7B illustrate a lighting apparatus of an embodiment in the present application form different perspectives.

FIG. 8 is an explosive diagram of a bulb in accordance with an embodiment of the present application.

### DETAILED DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

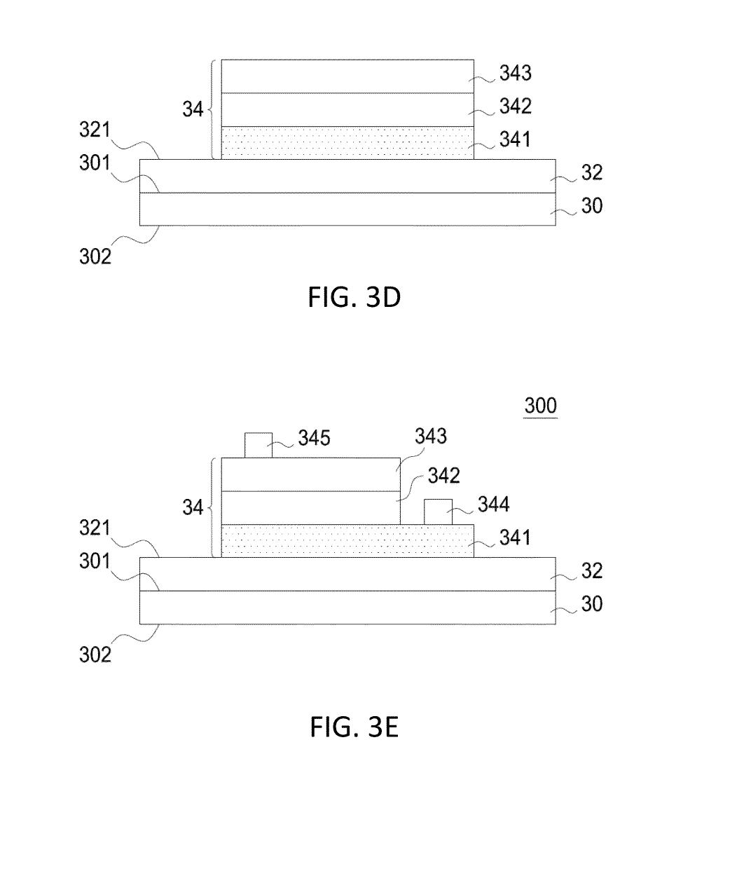

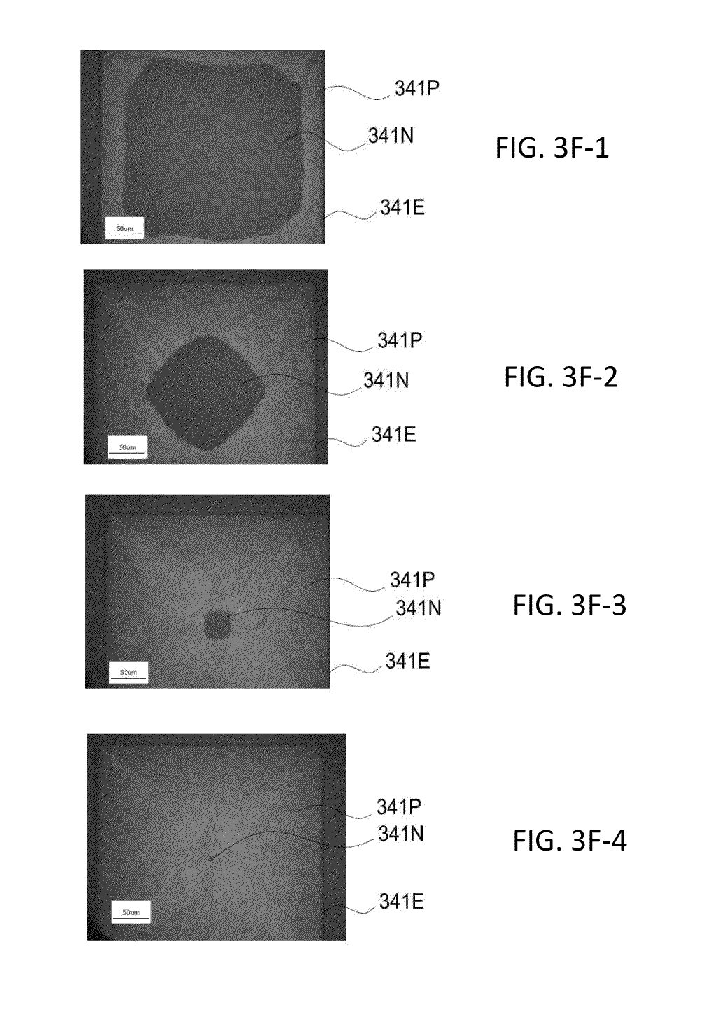

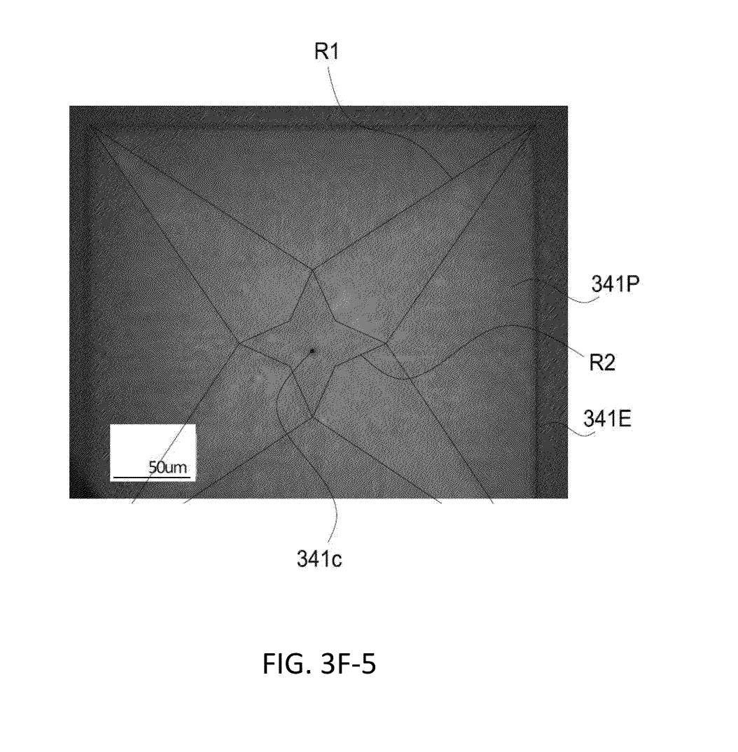

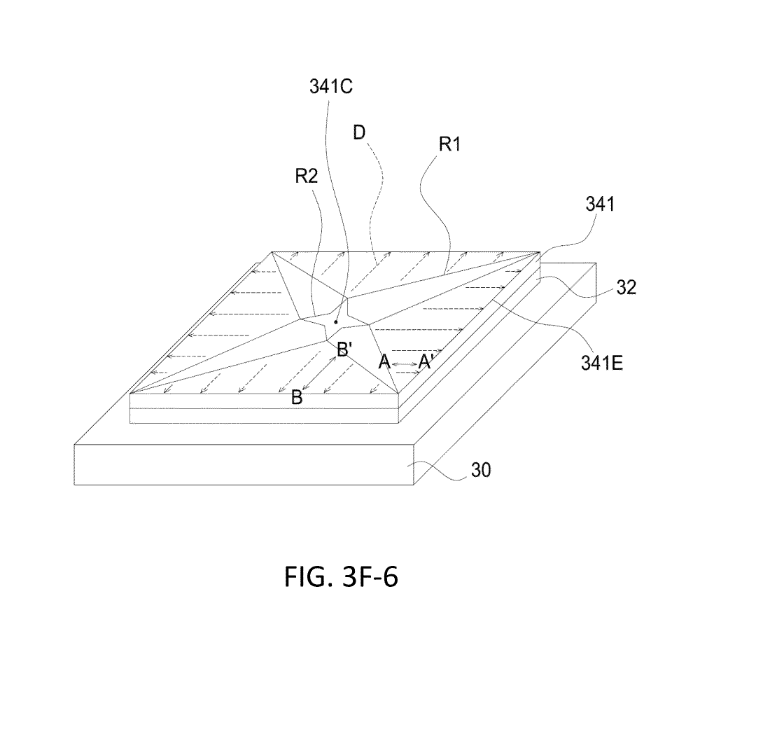

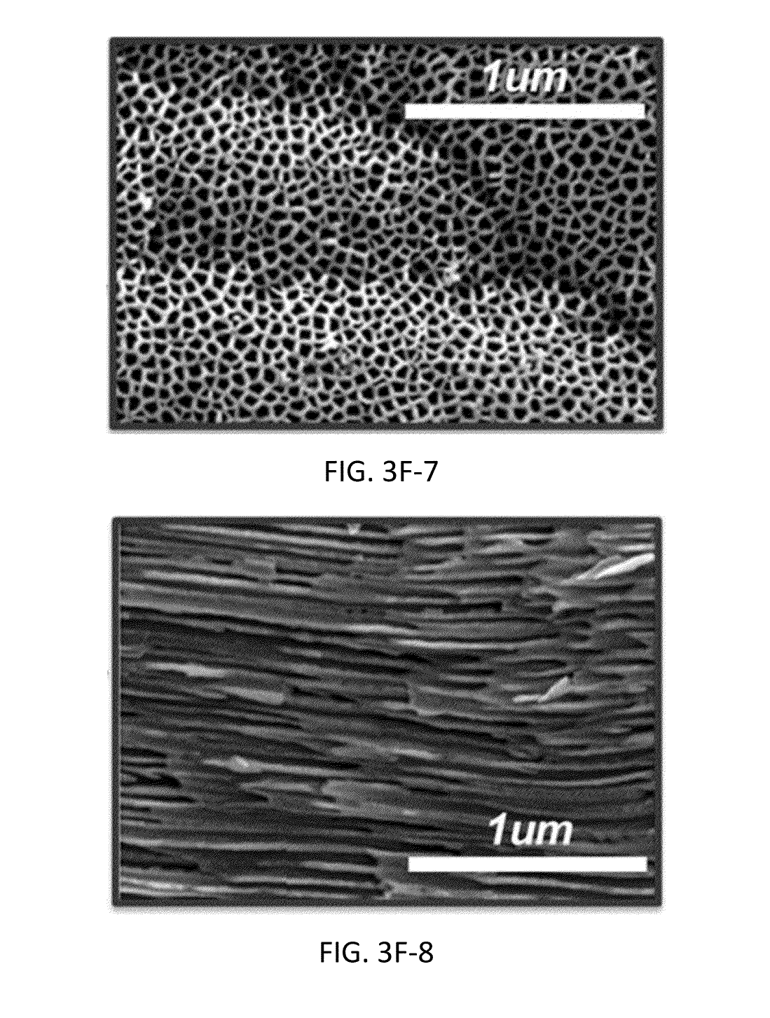

The present disclosure describes an optoelectronic device and a method of fabricating the optoelectronic device. In order to have a thorough understanding of the present disclosure, please refer to the following description and the illustrations of FIG. 3A to FIG. 8.

FIGS. 3A to 3E illustrate a process flow of the method of fabricating the optoelectronic device of a first embodiment of the present disclosure. FIG. 3A illustrates a substrate 30 including a first major surface 301 and a second major surface 302 wherein the first major surface 301 is opposite to the second major surface 302. FIG. 3B illustrates forming a transition layer 32 on the first major surface 301 of the substrate 30, and a semiconductor epitaxial stack 34 is formed on the transition layer 32, wherein the semiconductor epitaxial stack 34 includes a first conductive-type semiconductor layer 341 with the first doping concentration, an active layer 342, and a second conductive-type semiconductor layer 343. In one embodiment, the transition layer 32 can be an unintentional doped layer or an undoped layer. In another embodiment, the transition layer 32 is doped with the same conductive-type as that of the first conductive-type semiconductor layer 341 and has a second doping concentration lower than the first doping concentration.

The first conductive-type semiconductor layer 341 and the second conductive-type semiconductor layer 343 are different in electricity, polarity or dopant, or are different in semiconductor materials used for providing electrons and holes, wherein the semiconductor material layer can be single semiconductor material layer or multiple semiconductor material layers. The polarity can be chosen from any two of p-type, n-type and i-type. The active layer 342 is disposed between the first conductive-type semiconductor layer 341 and the second conductive-type semiconductor layer 343 respectively where the electrical energy and the light energy can be converted or stimulatively converted. The devices which can convert or stimulated convert the electrical energy into the light energy can be light-emitting diode, liquid crystal display, and organic light-emitting diode. The devices which can convert or be stimulatively converted the light energy into the electrical energy can be solar cell and optoelectronic diode. The material of the first conductive-type semiconductor layer 341, the active layer 342 and the second conductive-type semiconductor layer 343 includes one or more than one element selected form Ga, Al, In, As, P, N, Si. The material of the first conductive-type semiconductor layer 341, the active layer 342 and the second conductive-type semiconductor layer 343 can be aluminum gallium indium phosphide (AlGaInP) series material, aluminum gallium indium nitride (AlGaInN) series material and so on or ZnO-based semiconductor.

The structure of the active layer 342 can be single hetero structure (SH), double heterostructure (DH), double-side double heterostructure (DDH) or multi-quantum well (MQW) structure, wherein the wavelength of the light emitted from the active layer 342 can be changed by adjusting the number of the pairs of MQW.

FIG. 3B illustrates the semiconductor epitaxial stack 34 is etched to expose a part of the first surface 321 of the transition layer 32 by the lithography etching process.

Following, a lateral electrochemical etching process with an aqueous solution of at least one of H₂C₂O₄, KOH, H₂SO₄, H₃PO₄ and HF or their mixture is applied to the first conductive-type semiconductor layer 341 to form at least one hollow component in the first conductive-type semiconductor layer 341. The hollow component can be pore, void, bore, pinhole, cavity, or at least two hollow components can link into a mesh or porous structure.

In one embodiment, a protection layer (not shown) can be formed on the sidewall of the active layer 342 and/or the second conductive-type semiconductor layer 343 before performing the lateral electrochemical etching process to prevent the active layer 342 and the second conductive-type semiconductor layer 343 from the following lateral etching. The material of the protection layer can be a photoresist, amorphous Si, or metal layer such as Ti, Au or Pt.

In one embodiment, the DC voltage for the lateral electrochemical etching process can be 1˜5V, 1˜10V, or 1˜30V. The mole volume concentration of the etching solution for the lateral electrochemical etching process can be 0.1M˜5M, 0.1M˜10M or 0.1M˜30M.

In one embodiment, the first conductive-type semiconductor layer 341 is an n-type doping layer. The volume or the porosity of the hollow components formed inside the first conductive-type semiconductor layer 341 is related to the doping concentration of the first conductive-type semiconductor layer 341. In the same electrochemical etching process condition, the smaller volume or lower porosity of the hollow components is formed with the lower doping concentration of the first conductive-type semiconductor layer 341. Therefore, by adjusting the doping concentration of the first conductive-type semiconductor layer 341, the hollow components with different volume or porosity can be formed.

In one embodiment, the dopant material for doping the first conductive-type semiconductor layer 341 can be C, Ge, Sn or Pb and the doping concentration of the first conductive-type semiconductor layer 341 can be 1E15˜1E19 cm⁻³, 1E16˜1E19 cm⁻³, 1E17˜1E19 cm⁻³, 1E18˜1E19 cm⁻³, 5E18˜5E19 cm⁻³, 5E17˜5E19 cm⁻³ or 5E17˜5E18 cm⁻³.

In this embodiment, the width of the hollow components is defined as the largest size of the hollow components perpendicular with the normal line direction N of the substrate 30.

In one embodiment, the hollow component can be pore, void, bore, pinhole, cavity, and the width of the hollow component can be 5 nm-50 nm, 5 nm-100 nm, 5 nm-200 nm, 5 nm-300 nm or 5 nm-400 nm. In another embodiment, the hollow components can be multiple voids or porous structure. The average width of the plurality of the hollow components can be 1 nm-10 nm, 1 nm-100 nm, 5 nm-100 nm, 5 nm-200 nm or 5 nm-400 nm.

The porosity Φ of the plurality of the hollow components can be defined as the total volume of the hollow components Vᵥ divided by the overall volume V_{T} of the first conductive-type semiconductor layer 341

$$( φ = \frac{{V}_{V}}{{V}_{T}} ) .$$

In one embodiment, the porosity Φ of the plurality of the hollow components can be 10%-30%, 10%-40%, 10%-50% or 10%-65%. The porosity listed above can make the first conductive-type semiconductor layer 341 remain in contact with the substrate 30 stably. In other words, the lateral electrochemical etching process performed in the first conductive-type semiconductor layer 341 does not separate the first conductive-type semiconductor layer 341 and the substrate 30. In another embodiment, the plurality of the hollow components can be a regular array structure. For example, the plurality of the hollow components has the same size and forms a first photonic crystal structure. The stress can be released and the reflection and scattering of light can be enhanced by plurality of the hollow components.

Finally, FIG. 3E illustrates, two electrodes 344, 345 are formed on the first conductive-type semiconductor layer 341 and the second conductivity-type semiconductor layer 343 respectively to form a horizontal type optoelectronic device 300. The material of the electrodes 344, 345 can be Cr, Ti, Ni, Pt, Cu, Au, Al or Ag.

In one embodiment, the optoelectronic device 300 can be bonded on a submount to form a flip-chip structure.

The plurality of the hollow components inside the first conductive-type semiconductor layer 341 is empty spaces or cavities having a refractive index for acting as an air lens. Because of the difference of the refractive index of the plurality of the hollow components and the semiconductor layer, for example, the refractive index of the semiconductor layer is 2-3, and the refractive index of air is 1, the light transmitting into the plurality of the hollow components changes its emitting direction to outside the optoelectronic device 300 and increases the light emitting efficiency. Besides, the plurality of the hollow components can be a scattering center to change the direction of the photon and decrease the total reflection. By increasing the porosity of the hollow components, the effect mentioned above is increased.

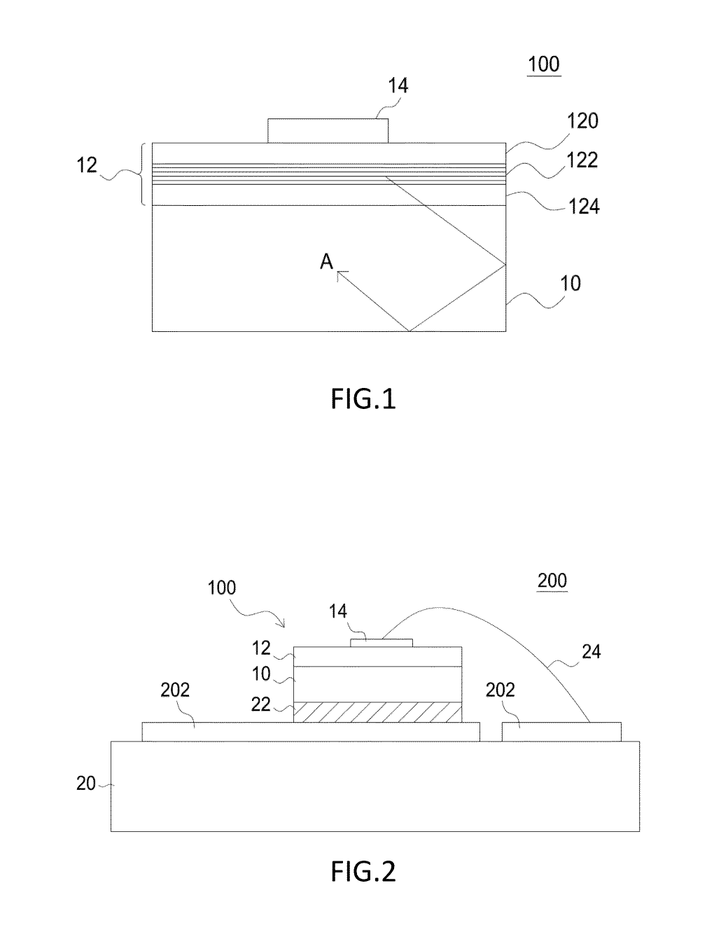

FIGS. 3F-1˜3F-4 illustrate the optical microscope images of the first conductive-type semiconductor layer 341 of the lateral electrochemical etching process in the present disclosure. Because the contrast of the etched first conductive-type semiconductor layer 341P and the un-etched first conductive-type semiconductor layer 341N is different, the etched first conductive-type semiconductor layer 341P with a plurality of the hollow components has lighter color and the un-etched first conductive-type semiconductor layer 341N has darker color.

FIGS. 3F-5˜3F-6 illustrate the schematic diagram of the upper surface and the three-dimensional schematic view of the first conductive-type semiconductor layer 341 in the present disclosure. As FIGS. 3F-1˜3F-6 illustrated, the change in appearance is observed by the optical microscope image along the time passing of performing the lateral electrochemical etching process. The lateral electrochemical etching started from the boundary 341E of the first conductive-type semiconductor layer 341 to the geometric center 341C of the first conductive-type semiconductor layer 341.

As FIG. 3F-6 illustrated, because the etching direction is defined by the current direction D of the lateral electrochemical etching, the four corners of the first conductive-type semiconductor layer 341 is also etched apart from the boundary 341E of the first conductive-type semiconductor layer 341. But because the etching direction and the etching rate of the etching from the boundary and the corner are different, a symmetry etching pattern can be formed on the upper surface of the first conductive-type semiconductor layer 341. In one embodiment, the symmetry etching pattern can be a first star shape R1 and the 4 tips of the astral is pointing to the corner of the first conductive-type semiconductor layer 341 and the symmetry point of the first star shape R1 is closed to the geometric center of the first conductive-type semiconductor layer 341.

In another embodiment, a second star shape R2 is formed on the upper surface of the first conductive-type semiconductor layer 341 and the second star shape R2 formed inside the first star shape R1. In another embodiment, the 4 tips of the astral of the second star shape R2 is pointing to the boundary of the first conductive-type semiconductor layer 341 and the symmetry point of 4 tips of the astral of the second star shape R2 is close to the geometric center of the first conductive-type semiconductor layer 341.

FIGS. 3F-7˜3F-8 illustrate scanning electron microscopy (SEM) pictures of the first conductive-type semiconductor layer 341 in the present disclosure. FIG. 3F-7 illustrates the cross-sectional view of A-A′ in FIG. 3F-6 of the first conductive-type semiconductor layer 341 and the shape of the plurality of the hollow components is a honeycomb shape. FIG. 3F-8 illustrates the cross-sectional view of B-B′ in FIG. 3F-6 of the first conductive-type semiconductor layer 341 and the shape of the plurality of the hollow components is a continuous empty voids shape.

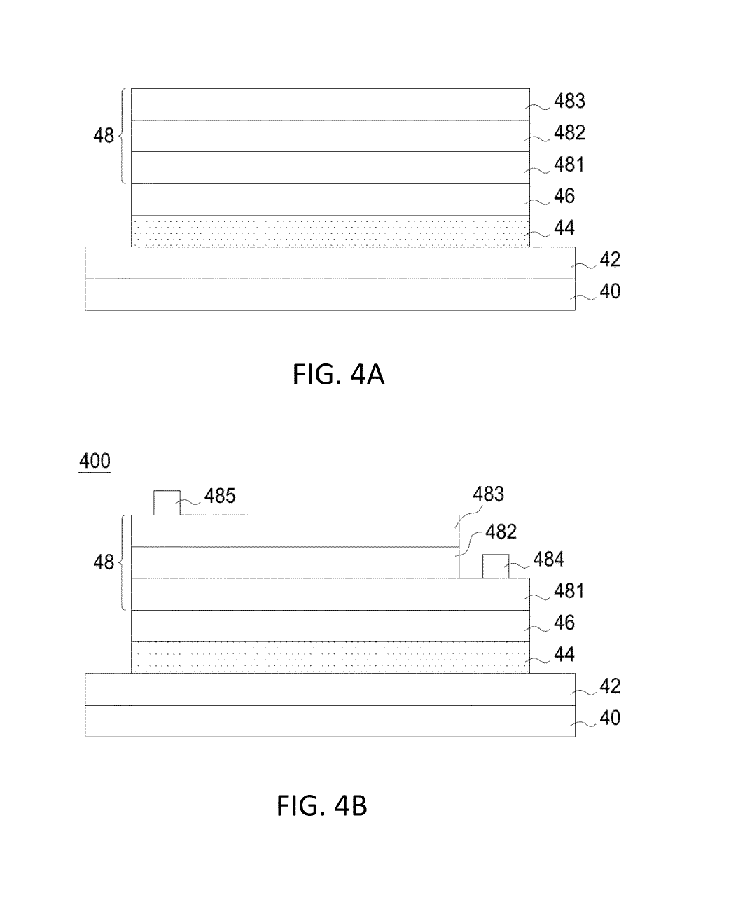

FIGS. 4A˜4B illustrate a process flow of a method of fabricating an optoelectronic device of the second embodiment in the present disclosure. FIG. 4A illustrates providing a substrate 40 and forming a transition layer 42 on the substrate 40. Following a first conductive-type semiconductor layer 44, a high-resistance layer 46 and a semiconductor epitaxial stack 48 are formed on the transition layer 42, wherein the semiconductor epitaxial stack 48 includes a second conductive-type semiconductor layer 481 with the first doping concentration, an active layer 482, and a third conductive-type semiconductor layer 483.

The second conductive-type semiconductor layer 481 and the third conductive-type semiconductor layer 483 are different in electricity, polarity or dopant, or are different in semiconductor materials used for providing electrons and holes, wherein the semiconductor material layer can be single semiconductor material layer or multiple semiconductor material layers. The polarity can be chosen from any two of p-type, n-type and i-type. The active layer 482 is disposed between the second conductive-type semiconductor layer 481 and the third conductive-type semiconductor layer 483 respectively where the electrical energy and the light energy can be converted or stimulatively converted. The devices which can convert or stimulatively convert the electrical energy into the light energy can be light-emitting diode, liquid crystal display, and organic light-emitting diode. The devices which can convert or be stimulatively converted the light energy into the electrical energy can be solar cell and optoelectronic diode. The material of the second conductive-type semiconductor layer 481, the active layer 482 and the third conductive-type semiconductor layer 483 includes one or more than one element selected form Ga, Al, In, As, P, N, Si. The material of the second conductive-type semiconductor layer 481, the active layer 482 and the third conductive-type semiconductor layer 483 can be aluminum gallium indium phosphide (AlGaInP) series material, aluminum gallium indium nitride (AlGaInN) series material and so on or ZnO-based semiconductor.

The structure of the active layer 482 can be single hetero structure (SH), double heterostructure (DH), double-side double heterostructure (DDH) or multi-quantum well (MQW) structure, wherein the wavelength of the light emitted from the active layer 482 can be changed by adjusting the number of the pairs of MQW.

In one embodiment, the transition layer 42 and the high-resistance layer 46 can be an unintentional doped layer or an undoped layer. In another embodiment, the transition layer 42 and the high-resistance layer 46 are doped with the same conductive-type as that of the first conductive-type semiconductor layer 44 and have a second doping concentration lower than the first doping concentration.

In another embodiment, the polarity or dopant of the high-resistance layer 46 is different with the first conductive-type semiconductor layer 44 and the second conductive-type semiconductor layer 481. In another embodiment, the polarity or dopant of the high-resistance layer 46 is the same with the third conductive-type semiconductor layer 483.

Following, the semiconductor epitaxial stack 48 is etched to expose a part of the transition layer 42 by the lithography etching process.

Following, a lateral electrochemical etching process with an aqueous solution of at least one of H₂C₂O₄, KOH, H₂SO₄, H₃PO₄ and HF or their mixture is applied to the first conductive-type semiconductor layer 44 to form at least one hollow component in the first conductive-type semiconductor layer 44. The hollow component can be pore, void, bore, pinhole, cavity, or at least two hollow components can link into a mesh or porous structure.

In this embodiment, with the high-resistance layer 46 in the lateral electrochemical etching process, the current tends to flow in the first conductive-type semiconductor layer 44 instead of flowing over the high-resistance layer 46 to the second conductive-type semiconductor layer 481 so that the hollow components is formed in the first conductive-type semiconductor layer 44 and the second conductive-type semiconductor layer 481 is not etched.

In one embodiment, the DC voltage for the lateral electrochemical etching process can be 1˜5V, 1˜10V, or 1˜30V. The mole volume concentration of the etching solution for the lateral electrochemical etching process can be 0.1M˜5M, 0.1M˜10M or 0.1M˜30M.

In one embodiment, the first conductive-type semiconductor layer 44 is an n-type doping layer. The volume or the porosity of the hollow components formed inside the first conductive-type semiconductor layer 44 is related to the doping concentration of the first conductive-type semiconductor layer 44. In the same electrochemical etching process condition, the smaller volume or lower porosity of the hollow components is formed with the lower doping concentration of the first conductive-type semiconductor layer 44. Therefore, by adjusting the doping concentration of the first conductive-type semiconductor layer 44, the hollow components with different width or porosity can be formed.

In one embodiment, the dopant material for doping the first conductive-type semiconductor layer 44 can be C, Ge, Sn or Pb and the doping concentration of the first conductive-type semiconductor layer 44 can be 1E15˜1E19 cm⁻³, 1E16˜1E19 cm⁻³, 1E17˜1E19 cm⁻³, 1E18˜1E19 cm⁻³, 5E18˜5E19 cm⁻³, 5E17˜5E19 cm⁻³ or 5E17˜5E18 cm⁻³.

In this embodiment, the width of the hollow component is defined as the largest size of the hollow component perpendicular with the normal line direction N of the substrate 40.

In one embodiment, the hollow component can be pore, void, bore, pinhole, cavity, and the width of the hollow component can be 5 nm-50 nm, 5 nm-100 nm, 5 nm-200 nm, 5 nm-300 nm or 5 nm-400 nm. In another embodiment, the hollow components can be multiple voids or porous structure. The average width of the plurality of the hollow components can be 1 nm-10 nm, 1 nm-100 nm, 5 nm-100 nm, 5 nm-200 nm or 5 nm-400 nm.

The porosity Φ of the plurality of the hollow components can be defined as the total volume of the hollow components Vᵥ divided by the overall volume V_{T} of the first conductive-type semiconductor layer 44

$$( φ = \frac{{V}_{V}}{{V}_{T}} ) .$$

In one embodiment, the porosity Φ of the plurality of the hollow components can be 10%-30%, 10%-40%, 10%-50% or 10%-65%. The porosity listed above can make the first conductive-type semiconductor layer 44 remain in contact with the substrate 40 stably. In other words, the lateral electrochemical etching process performed in the first conductive-type semiconductor layer 44 does not separate the first conductive-type semiconductor layer 44 and the substrate 40.

In another embodiment, the plurality of the hollow components can be a regular array structure. For example, the plurality of the hollow components has the same size and forms a first photonic crystal structure. The stress can be released and the reflection and scattering of light can be enhanced by plurality of the hollow components.

Finally, FIG. 4B illustrates two electrodes 484, 485 formed on the second conductive-type semiconductor layer 481 and the third conductivity-type semiconductor layer 483 respectively to form a horizontal type optoelectronic device 400. In this embodiment, the electrode 484 is formed on the second conductive-type semiconductor layer 481 and has better conductivity because of no hollow components formed inside the second conductive-type semiconductor layer 481.

In one embodiment, the optoelectronic device 400 can be bonded on a submount to form a flip-chip structure.

The plurality of the hollow components inside the first conductive-type semiconductor layer 44 is empty spaces or cavities having a refractive index for acting as an air lens. Because of the difference of the refractive index of the plurality of the hollow components and the semiconductor layer, for example, the refractive index of the semiconductor layer is 2˜3, and the refractive index of air is 1, the light transmitting into the plurality of the hollow components changes its emitting direction to outside the optoelectronic device 400 and increases the light emitting efficiency. Besides, the plurality of the hollow components can be a scattering center to change the direction of the photon and decrease the total reflection. By increasing the porosity of the hollow components, the effect mentioned above is increased. Besides, the shape of the hollow components of this embodiment can be formed as the first embodiment and forms at least one symmetry shape on the upper surface of the first conductive-type semiconductor layer 44. The fabricating method and the feature of the hollow components is the same with the first embodiment.

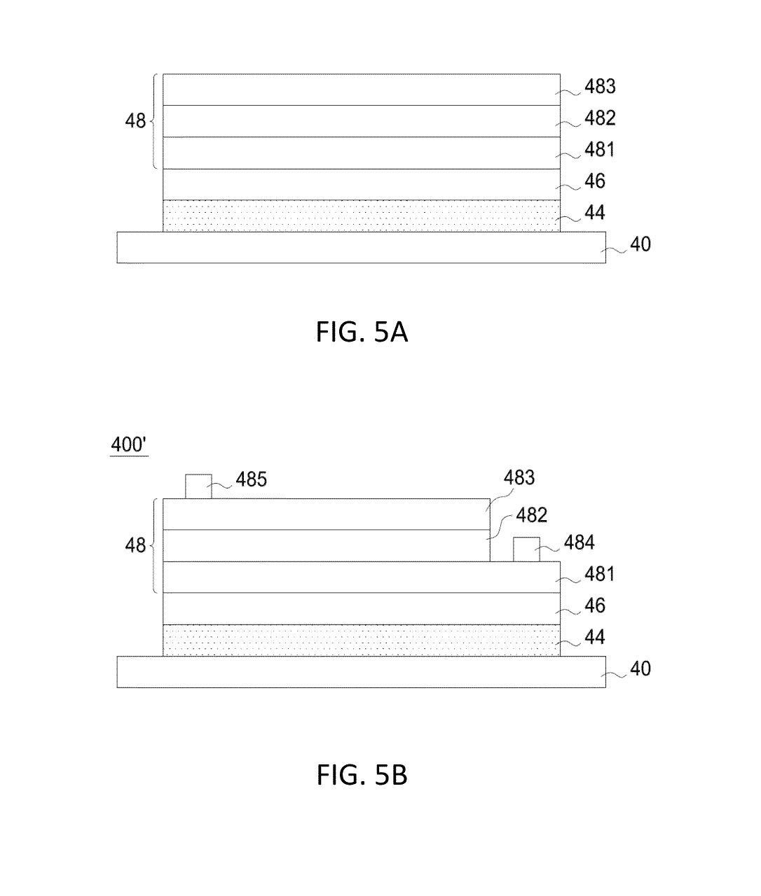

FIGS. 5A˜5B illustrate a process flow of a method of fabricating an optoelectronic device of the third embodiment in the present disclosure. This embodiment is a modified embodiment of the second embodiment. FIG. 5A illustrates providing a substrate 40 and forming a first conductive-type semiconductor layer 44, a high-resistance layer 46 and a semiconductor epitaxial stack 48 on the transition layer 42, wherein the semiconductor epitaxial stack 48 includes a second conductive-type semiconductor layer 481 with the first doping concentration, an active layer 482, and a third conductive-type semiconductor layer 483.

In one embodiment, the high-resistance layer 46 can be an unintentional doped layer or an undoped layer. In another embodiment, the high-resistance layer 46 is doped with the same conductive-type as that of the first conductive-type semiconductor layer 44 and has a second doping concentration lower than the first doping concentration.

Following, the semiconductor epitaxial stack 48 is etched to expose a part of the substrate 40 by the lithography etching process.

Following, a lateral electrochemical etching process with an aqueous solution of at least one of H₂C₂O₄, KOH, H₂SO₄, H₃PO₄ and HF or their mixture is applied to the first conductive-type semiconductor layer 44 to form at least one hollow component in the first conductive-type semiconductor layer 44. The hollow component can be pore, void, bore, pinhole, cavity, or at least two hollow components can link into a mesh or porous structure.

In this embodiment, with the high-resistance layer 46 in the lateral electrochemical etching process, the current tends to flow in the first conductive-type semiconductor layer 44 instead of flowing over the high-resistance layer 46 to the second conductive-type semiconductor layer 481 so that the hollow components is formed in the first conductive-type semiconductor layer 44 and the second conductive-type semiconductor layer 481 is not etched.

In one embodiment, the DC voltage for the lateral electrochemical etching process can be 1˜5V, 1˜10V, or 1˜30V. The mole volume concentration of the etching solution for the lateral electrochemical etching process can be 0.1M˜5M, 0.1M˜10M or 0.1M˜30M.

Finally, FIG. 5B illustrates two electrodes 484, 485 formed on the second conductive-type semiconductor layer 481 and the third conductivity-type semiconductor layer 483 respectively to form a horizontal type optoelectronic device 400′. In this embodiment, the electrode 484 is formed on the second conductive-type semiconductor layer 481. The electrode 484 can have better conductivity because there is no hollow component formed inside the second conductive-type semiconductor layer 481.

In one embodiment, the optoelectronic device 400′ can be bonded on a submount to form a flip-chip structure.

In this embodiment, besides the first conductive-type semiconductor layer 44 is directly formed on the substrate 40, the fabricating method, fabricating material and the volume and the feature of the hollow components are the same with the second embodiment. Besides, the shape of the hollow components of this embodiment can be formed as those disclosed in the first embodiment and at least one symmetry shape can be formed on the upper surface of the first conductive-type semiconductor layer 44.

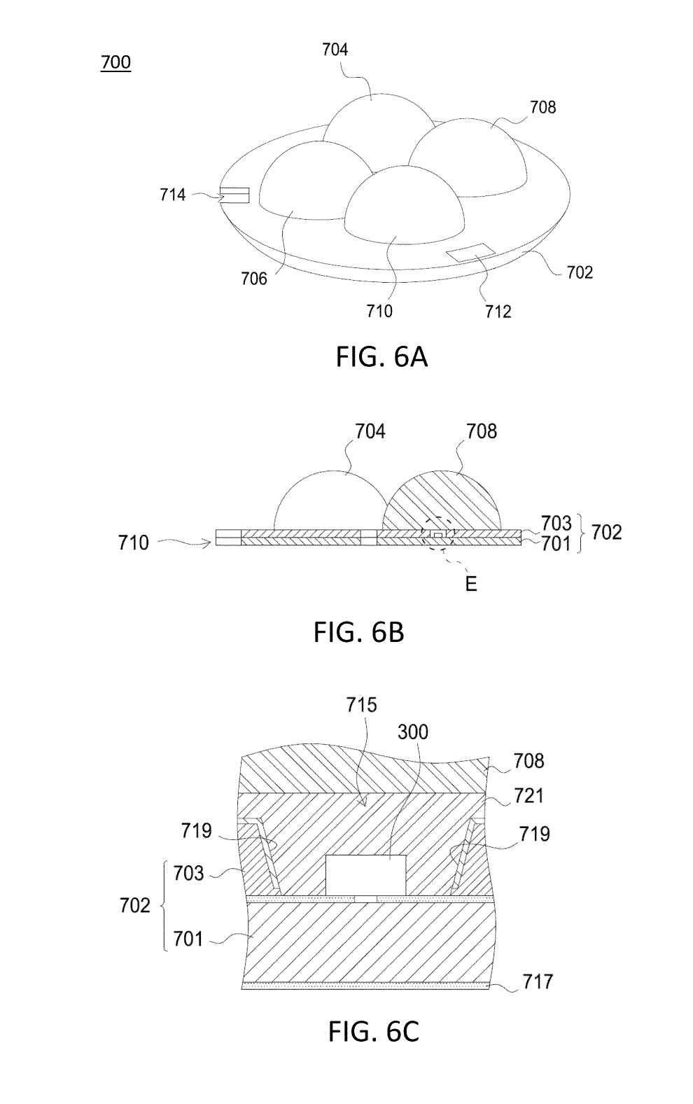

FIGS. 6A-6C illustrate an LED module of an application in the present disclosure. FIG. 6A is an external perspective view illustrating an optoelectronic device module 700 including a submount 702, an optoelectronic device (not shown) described above, a plurality of lens 704, 706, 708, 710, and two power supply terminals 712, 714. The LED module 700 is attached to a lighting unit 800 (mentioned later).

FIG. 6B is a planar view illustrating the optoelectronic device module 700, and FIG. 6C is an enlarged view illustrating a portion E shown in FIG. 6B. As FIG. 6B shows, the submount 702 including an upper subunit 703 and a lower subunit 701, and at least one surface of the lower subunit 701 is contacted with the upper subunit 703. The lenses 704, 708 are formed on the upper subunit 703. At least one through hole 715 is formed on the upper subunit 703 and at least one of the optoelectronic device 300 is formed inside the through hole 715 and contacted with the lower subunit 701. Besides, the optoelectronic device 300 is encapsulated by an encapsulating material 721 wherein the material of the encapsulating material 721 may be a silicone resin, an epoxy resin or the like. And a lens 708 is optionally formed on the encapsulating material 721. In one embodiment, a reflecting layer 719 is formed on the sidewall of the through hole 715 to increase the light emitting efficiency. A metal layer 717 can be formed on the lower surface of the lower subunit 701 for improving heat dissipation.

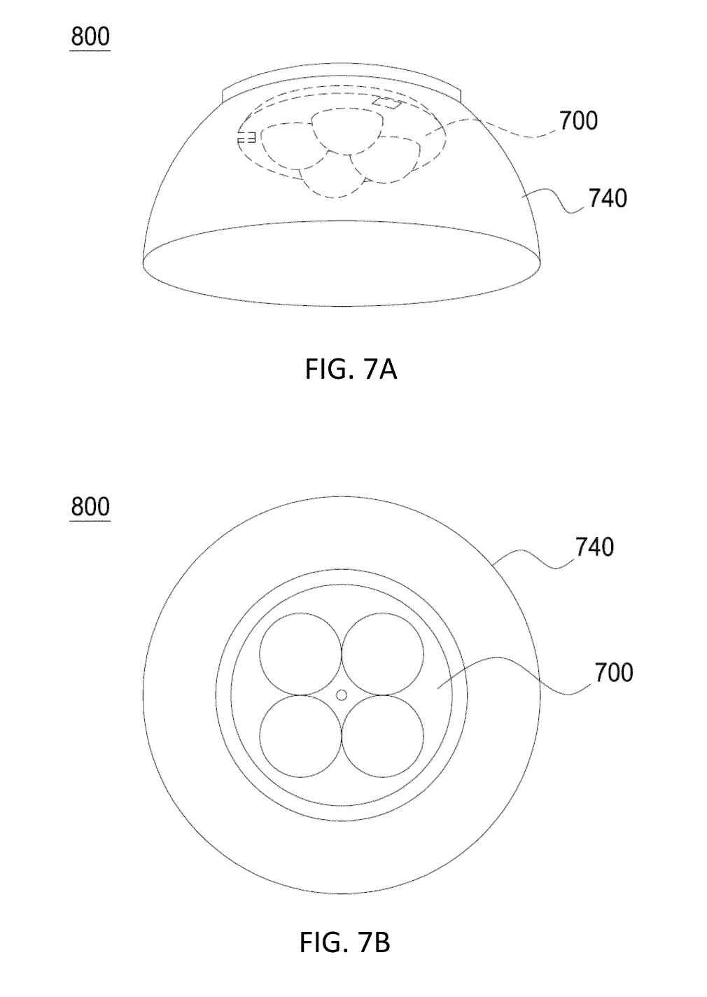

FIGS. 7A-7B illustrate a lighting apparatus of an embodiment in the present application form different perspectives. The lighting apparatus 800 includes an optoelectronic device module 700, a case 740, a power supply circuit (not shown) to supply current to the lighting apparatus 800 and a control unit (not shown) to control the power supply circuit. The lighting apparatus 800 can be an illumination device, such as street lamps, headlights or indoor illumination light source, and can be a traffic sign or a backlight module of the display panel.

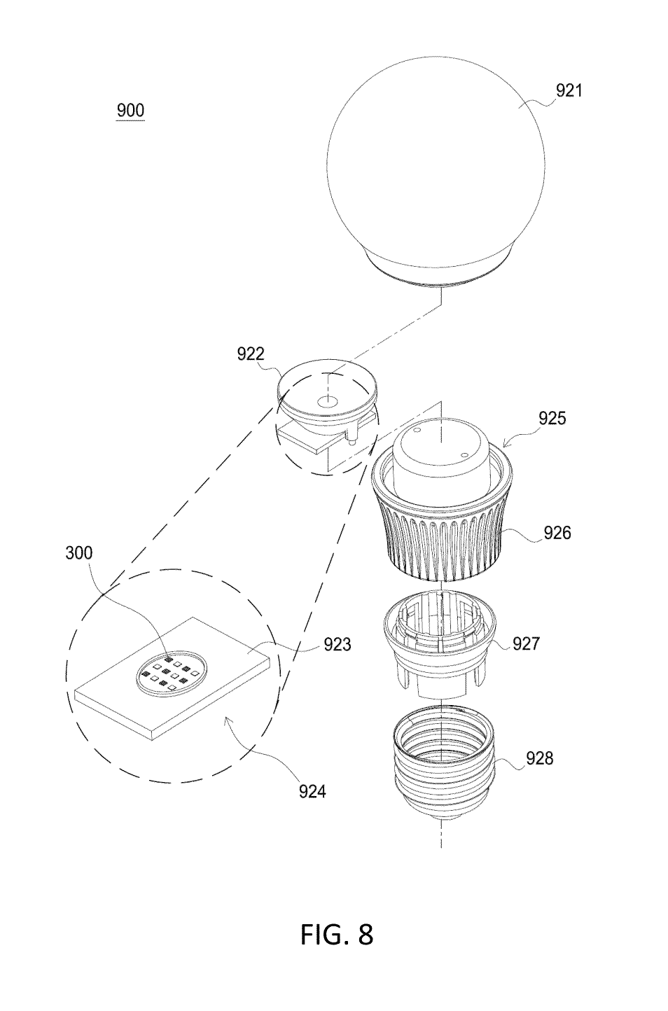

FIG. 8 shows an explosive diagram of a bulb in accordance with another application of the present application. The bulb 900 includes a cover 821, a lens 822, a lighting module 824, a lamp holder 825, a heat sink 826, a connecting part 827, and an electrical connector 828. The lighting module 824 includes a carrier 823 and a plurality of optoelectronic device 300 of any one of the above mentioned embodiments on the carrier 823.

Specifically, the optoelectronic device 300, 400, 400′ includes light-emitting diode (LED), photodiode, photo resister, laser diode, infrared emitter, organic light-emitting diode and solar cell. The substrate 30, 40 can be a growing or carrying base. The material of the substrate 30, 40 includes an electrically conductive substrate, electrically insulating substrate, transparent substrate, or opaque substrate. The material of the electrically conductive substrate can be metal such as Ge and GaAs, oxide such as LiAlO₂ and ZnO, nitrogen compound such as GaN and AlN, phosphide such as InP, silicon compound such as SiC, or Si. The material of the transparent substrate can be chosen from sapphire (Al₂O₃), LiAlO₂, ZnO, GaN, AlN, glass, diamond, CVD diamond, diamond-like carbon (DLC), spinel (MgAl₂O₃), SiOₓ, or LiGaO₂.

A buffer layer (not shown) can be selectively disposed between the transition layer 32, 42 and the substrate 30, 40 or between the first conductive-type semiconductor layer 44 and the substrate 30, 40. The buffer layer is between the two material systems to transit the material system to the semiconductor system layer. For the structure of the light-emitting diode, the buffer layer is used to reduce the crystal mismatch between two materials. On the other hand, the buffer layer includes a single layer, multiple layers or a structure which includes two materials or two separated structures. The material of the buffer layer can be organic material, inorganic material, metal or semiconductor material. The structure of the buffer layer can be a reflector layer, a thermally conductive layer, an electrically conductive layer, an ohmic contact layer, an anti-deformation layer, a stress release layer, a bonding layer, a wavelength conversion layer or a mechanically fixing structure. In one embodiment, the material of the buffer layer can be MN or GaN, and the buffer layer can be formed by sputtering or atomic layer deposition (ALD).

A contacting layer (not shown) can be selectively formed on the semiconductor epitaxial stack 34, 48 away from the substrate 30, 40. Specifically, the contacting layer can be optical layer, electrical layer, or the combination thereof. The optical layer can change the radiation or the light from or entering the active layer 342, 482, wherein the optical layer can change the frequency, the wavelength, the intensity, the flux, the efficiency, the color temperature, rendering index, light field, angle of view, etc. The electrical layer can change the value, density, distribution of voltage, resistance, current and capacitance of any two relative sides of the contacting layer. The material of the contacting layer includes oxide such as conductive oxide, transparent oxide and the oxide with the transparency over 50%, metal such as transparent metal and the metal with transparency over 50%, organic material, inorganic material, fluoresce material, ceramic, semiconductor material and doping semiconductor material. In some applications, the material of the contacting layer can be InTiO, CdSnO, SbSnO, InZnO, ZnAlO or ZnSnO. If the material of the contacting layer is transparent metal, the thickness of the contacting layer is in a range of 0.005 μm˜0.6 μm.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. A method of fabricating an optoelectronic device comprising, providing a substrate, wherein the substrate comprises a first major surface and a second major surface opposite to the first major surface;
forming a semiconductor epitaxial stack on the first major surface including a first conductive-type semiconductor layer having a first doping concentration, an active layer, and a second conductive-type semiconductor layer wherein the semiconductor epitaxial stack having four boundaries and a geometric center; and
forming a plurality of the hollow components in the first conductive-type semiconductor layer wherein the plurality of the hollow components is formed from the boundary of the semiconductor epitaxial stack to the geometric center of the semiconductor epitaxial stack.

2. The method of fabricating an optoelectronic device of claim 1, wherein the plurality of the hollow components forms a symmetric shape, and/or the plurality of the hollow components is symmetrical with the geometric center of the first conductive-type semiconductor layer, and/or the plurality of the hollow components forms a first star shape.

3. The method of fabricating an optoelectronic device of claim 1, further comprising forming a transition layer between the substrate and the first conductive-type semiconductor layer, and wherein the transition layer is an unintentional doped layer or an updoped layer.

4. The method of fabricating an optoelectronic device of claim 3, wherein the first conductive-type semiconductor layer having a first doping concentration and the transition layer having a second doping concentration and the transition layer is doped with the same conductive-type as that of the first conductive-type semiconductor layer and is lower than the first doping concentration.

5. The method of fabricating an optoelectronic device of claim 1, further comprising performing a lateral electrochemical etching in the first conductivity-type semiconductor layer to form the plurality of the hollow components.

6. The method of fabricating an optoelectronic device of claim 5, wherein the lateral electrochemical etching comprising applying a bias voltage in the first conductivity-type semiconductor layer and the porosity of the plurality of the hollow components in the first conductive-type semiconductor layer can be proportional to the applied bias voltage.

7. The method of fabricating an optoelectronic device of claim 1, wherein the plurality of the hollow components forms a mesh structure, a porous structure, or a regular array and/or the porosity of the plurality of the hollow components in the first conductive-type semiconductor layer is 10-65%.

8. The method of fabricating an optoelectronic device of claim 1, wherein the plurality of the hollow components in the first conductive-type semiconductor layer keeps the first conductive-type semiconductor layer remain in contact with the substrate stably.

9. The method of fabricating an optoelectronic device of claim 1, further comprising etching the first conductive-type semiconductor layer, the active layer and the second conductive-type semiconductor layer to expose the first major surface of the substrate or the first conductive-type semiconductor layer.

10. The method of fabricating an optoelectronic device of claim 1, further comprising forming a protection layer to cover the active layer and the second conductive-type semiconductor layer.

11. The method of fabricating an optoelectronic device of claim 1, further comprising forming a third second conductive-type semiconductor layer between the first second conductive-type semiconductor layer and the active layer and the third second conductive-type semiconductor layer is doped with the same conductive-type as that of the first conductive-type semiconductor layer.

12. The method of fabricating an optoelectronic device of claim 11, further comprising forming a high-resistance layer between the first second conductive-type semiconductor layer and the third second conductive-type semiconductor layer and the doping conductivity of the third second conductive-type semiconductor layer and the high-resistance layer can be the same or different.

13. An optoelectronic device comprising:
a substrate;
a first conductive-type semiconductor layer, an active layer, and a second conductive-type semiconductor layer formed on the substrate wherein the first conductive-type semiconductor layer having four boundaries, and the four boundaries further defining a geometric center and four corners; and
a plurality of the hollow components formed in the first conductive-type semiconductor layer wherein the plurality of the hollow components is formed from the boundary of the optoelectronic device to the geometric center of the optoelectronic device and the plurality of the hollow components has a porosity.

14. The optoelectronic device of claim 13, wherein the plurality of the hollow components is formed in a symmetric shape, and/or the plurality of the hollow components are symmetrical with the geometric center of the first conductive-type semiconductor layer,

15. The optoelectronic device of claim 13, wherein the plurality of the hollow components forms a first star shape having four tips, and/or the four tips of the first star shape is pointing to the four corners of the first conductive-type semiconductor layer and the symmetry point of the first star shape is closed to the geometric center of the first conductive-type semiconductor layer.

16. The optoelectronic device of claim 13, further comprising a transition layer formed between the substrate and the first conductive-type semiconductor layer, and wherein the transition layer is an unintentional doped layer or an updoped layer, and/or the first conductive-type semiconductor layer having a first doping concentration and the transition layer having a second doping concentration and the transition layer is doped with the same conductive-type as that of the first conductive-type semiconductor layer and is lower than the first doping concentration.

17. The optoelectronic device of claim 13, wherein the plurality of the hollow components forms a mesh structure, a porous structure, or a regular array and/or the porosity of the plurality of the hollow components in the first conductive-type semiconductor layer is 10-65%.

18. The optoelectronic device of claim 15, wherein the plurality of the hollow components forms a second star shape in the first conductive-type semiconductor layer, and the second star shape formed inside the first star shape and/or the second star shape has four tips of the astral and the symmetry point of the four tips of the astral of the second star shape is closed to the geometric center of the first conductive-type semiconductor layer.

19. The optoelectronic device of claim 13, further comprising a third second conductive-type semiconductor layer formed between the first second conductive-type semiconductor layer and the active layer and the third second conductive-type semiconductor layer is doped with the same conductive-type as that of the first conductive-type semiconductor layer.

20. The optoelectronic device of claim 19, further comprising a high-resistance layer formed between the first second conductive-type semiconductor layer and the third second conductive-type semiconductor layer and the doping conductivity of the third second conductive-type semiconductor layer and the high-resistance layer can be the same or different.
